(19) United States
(12) Patent Application Publication
(10) Pub. No.: US 2026/0302392 A1
(43) Pub. Date: Oct. 1, 2026

(54) APPARATUS FOR DIAGNOSING BATTERY AND METHOD THEREOF

(71) Applicants: HYUNDAI MOTOR COMPANY, SEOUL (KR); KIA CORPORATION, SEOUL (KR); UNIST(ULSAN NATIONAL INSTITUTE OF SCIENCE AND TECHNOLOGY), ULSAN (KR)

(72) Inventors: Sam Ick Son, Hwaseong-si (KR); Ki Yoon Bae, Hwaseong-si (KR); Ji Young Kim, Hwaseong-si (KR); Soon Jae Jung, Ulsan (KR); Hyun Wook Lee, Ulsan (KR)

(73) Assignees: HYUNDAI MOTOR COMPANY, SEOUL (KR); KIA CORPORATION, SEOUL (KR); UNIST(ULSAN NATIONAL INSTITUTE OF SCIENCE AND TECHNOLOGY), ULSAN (KR)

(21) Appl. No.: 19/347,321

(22) Filed: Oct. 1, 2025

(30) Foreign Application Priority Data
Mar. 27, 2025 (KR) 10-2025-0039724

(51) Int. Cl. H01M 10/44; G01L 13/06; H01M 10/42; H02J 7/00

(52) U.S. Cl. CPC H01M 10/44; G01L 13/06; H01M 10/4285; H02J 7/60; H02J 7/80

(57) ABSTRACT

A battery diagnosing apparatus calculates an integral value based on first data, and second data with a predetermined range, calculates a Full Width at Half Maximum (FWHM) value associated with a width of the second data relative to half a peak value of the first data, and determines a condition of a battery cell based on the integral value and the FWHM value. The first data includes at least one of: a rate of change of pressure of the battery cell; an acceleration of the rate of change of the pressure; or any combination thereof; and the second data includes at least one of: an areal capacity comprising a capacity per unit area of an electrode plate of the battery cell; a charging time of the battery cell; or any combination thereof.

### CROSS REFERENCE TO RELATED APPLICATIONS

This application claims the benefit of priority to Korean Patent Application No. 10-2025-0039724, filed in the Korean Intellectual Property Office on Mar. 27, 2025, the entire contents of which are incorporated herein by reference.

### TECHNICAL FIELD

The present disclosure relates to a battery diagnosing apparatus and a method thereof, and more particularly, relates to a technology for determining the internal state of a battery cell.

### BACKGROUND

At present, increasing carbon neutrality policies are driving interest in plug-in hybrids and electric vehicles, which utilize lithium-ion batteries instead of traditional internal combustion engines. As a result, consumers are demanding high performance from their batteries in terms of charging speed, power output, and lifespan, and there is an ever-increasing focus on battery safety.

Typical lithium-ion batteries use an organic liquid electrolyte that is flammable and volatile, and thus there is a risk of fire and explosion in the event of an accident such as an external impact or electrolyte leakage. Various safety devices are additionally applied to the battery pack to prevent the issues, but they may reduce the energy density of the battery within the same volume.

To overcome these limitations, research on all-solid-state batteries with inorganic solid electrolytes, which may replace organic liquid electrolytes, is actively underway. The all-solid-state batteries use electrolytes in a non-flammable and inorganic solid state, which significantly reduces the risk of fire and explosion compared to conventional lithium-ion batteries. Additionally, the battery pack thereof may be designed in a variety of shapes and structures, allowing for more flexible development.

However, just like using liquid electrolytes, the all-solid-state batteries still have issues such as volume changes during charging and discharging, side reactions and pore formation at the electrode-electrolyte interface, and dendritic lithium growth. These issues may be further aggravated by the physical contact characteristics at the solid-solid interface.

In particular, the loss of particle contact at the cathode-electrolyte interface may cause overpotential, resulting in unintended dendritic lithium growth, which not only degrades the performance of the battery but ultimately causes an internal short circuit, rendering the battery unusable.

Accordingly, it is necessary to develop a technique that may estimate the inhomogeneity of lithium metal electrodeposition and lithium metal plating that occurs within a cathode while the all-solid-state batteries are driven.

### SUMMARY

The present disclosure was made to solve the above-mentioned problems occurring in the prior art, while the advantages achieved by the prior art are maintained intact.

An aspect of the present disclosure provides a battery diagnosing apparatus capable of detecting the plating of metal on an electrode during the operation of a battery, and a method thereof.

An aspect of the present disclosure provides a battery diagnosing apparatus capable of quantitatively analyzing the homogeneity of the electrode internal reaction and the presence of lithium electrodeposition based on pressure change data during the charging process of a battery, and a method thereof.

An aspect of the present disclosure provides a battery diagnosing apparatus capable of non-destructively evaluating the condition of a battery cell by quantifying the heterogeneity of the electrodeposition reaction using the first-order derivative value and the second-order derivative value of the pressure of the battery cell, and a method thereof.

An aspect of the present disclosure provides a battery diagnosing apparatus capable of providing a criterion for comparing lithium electrodeposition and reaction heterogeneity under various conditions by normalizing the integral area of a graph for the second-order derivative value of the pressure of the battery cell to a Full Width at Half Maximum (FWHM) value, and a method thereof.

An aspect of the present disclosure provides a battery diagnosing apparatus capable of providing a criterion for evaluating the stability of a battery, by quantitatively analyzing the time at which lithium plating begins within a battery cell and the progress of the lithium plating, and a method thereof.

An aspect of the present disclosure provides a battery diagnosing apparatus capable of extending battery life and improving safety by detecting lithium dendrite growth issues occurring in battery cells early, and a method thereof.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, a battery diagnosing apparatus includes a memory that stores a program instruction, and a processor that executes the program instruction. The processor calculates an integral value based on first data, and second data with a predetermined range, calculates a Full Width at Half Maximum (FWHM) value associated with a width of the second data, relative to half a peak value of the first data, and determines a condition of a battery cell based on the integral value and the FWHM value. The first data includes at least one of a rate of change of pressure of the battery cell, or an acceleration of the rate of change of the pressure, or any combination thereof, and the second data includes at least one of areal capacity including capacity per unit area of an electrode plate of the battery cell, or a time during which the battery cell is charged, or any combination thereof.

In an embodiment, the processor may identify a pressure value of the battery cell measured by a pressure sensor that measures the pressure of the battery cell, calculate the rate of change of the pressure by differentiating the pressure value, and calculate the acceleration of the rate of change of the pressure by differentiating the rate of change of the pressure.

In an embodiment, the processor may determine the condition of the battery cell based on a characteristic value obtained by dividing the integral value by the FWHM value.

In an embodiment, the processor may determine the condition of the battery cell based on the result of comparing the characteristic value with a reference value associated with a dendrite phenomenon.

In an embodiment, the processor may determine the condition of the battery cell as a state where the dendrite phenomenon occurs at an electrode of the battery cell, based on a result indicating that the characteristic value exceeds the reference value.

In an embodiment, the reference value may be determined based on an electrochemical operating principle at an electrode of the battery cell.

In an embodiment, the processor may determine the condition of the battery cell based on the capacity of a cathode of the battery cell being lower than the capacity of an anode of the battery cell.

In an embodiment, the processor may determine the condition of the battery cell based on the integral value and the FWHM value after a charge cycle of the battery cell exceeds a predetermined number of times.

In an embodiment, the processor may calculate the integral value from a first time point to a second time point. The first time point may include a time point at which charging of the battery cell begins, or a time point at which the areal capacity is 0, and the second time point may include a time point at which the acceleration of the rate of change of pressure of the battery cell becomes 0.

In an embodiment, the processor may stop charging the battery cell based on determining that the degree to which a dendrite phenomenon occurs at an electrode of the battery cell exceeds a predetermined threshold value.

According to an aspect of the present disclosure, a battery diagnosing method includes calculating, by a processor, an integral value based on first data, and second data with a predetermined range, calculating, by the processor, a FWHM value associated with a width of the second data relative to half a peak value of the first data, and determining, by the processor, a condition of a battery cell based on the integral value and the FWHM value. The first data includes at least one of: a rate of change of pressure of the battery cell; an acceleration of the rate of change of the pressure; or any combination thereof, and the second data includes at least one of: an areal capacity comprising a capacity per unit area of an electrode plate of the battery cell; a charging time of the battery cell, or any combination thereof.

In the battery diagnosing method according to an embodiment, the calculating, by the processor, of the integral value based on the first data, and the second data with the predetermined range may include identifying, by the processor, a pressure value of the battery cell measured by a pressure sensor that measures the pressure of the battery cell, calculating, by the processor, the rate of change of the pressure by differentiating the pressure value, and calculating, by the processor, the acceleration of the rate of change of the pressure by differentiating the rate of change of the pressure.

In the battery diagnosing method according to an embodiment, the determining, by the processor, of the condition of the battery cell based on the integral value and the FWHM value may include determining, by the processor, the condition of the battery cell based on a characteristic value obtained by dividing the integral value by the FWHM value.

In the battery diagnosing method according to an embodiment, the determining, by the processor, of the condition of the battery cell based on the integral value and the FWHM value may include determining, by the processor, the condition of the battery cell based on a result of comparing the characteristic value with a reference value associated with a dendrite phenomenon.

In the battery diagnosing method according to an embodiment, the determining, by the processor, of the condition of the battery cell based on the integral value and the FWHM value may include determining, by the processor, the condition of the battery cell as a state where the dendrite phenomenon occurs at an electrode of the battery cell, based on a result indicating that the characteristic value exceeds the reference value.

In the battery diagnosing method according to an embodiment, the reference value may be determined based on an electrochemical operating principle at an electrode of the battery cell.

In the battery diagnosing method according to an embodiment, the determining, by the processor, of the condition of the battery cell based on the integral value and the FWHM value may include determining, by the processor, the condition of the battery cell based on capacity of a cathode of the battery cell being lower than capacity of an anode of the battery cell.

In the battery diagnosing method according to an embodiment, the determining, by the processor, of the condition of the battery cell based on the integral value and the FWHM value may include determining, by the processor, the condition of the battery cell based on the integral value and the FWHM value after a charge cycle of the battery cell exceeds a predetermined number of times.

In the battery diagnosing method according to an embodiment, the calculating, by the processor, of the integral value based on the first data, and the second data with the predetermined range may include calculating, by the processor, the integral value from a first time point to a second time point. The first time point may include a time point at which charging of the battery cell begins, or a time point at which the areal capacity is 0, and the second time point may include a time point at which the acceleration of the rate of change of pressure of the battery cell becomes 0.

The battery diagnosing method according to an embodiment may include stopping, by the processor, charging of the battery cell based on determining that the degree to which a dendrite phenomenon occurs at an electrode of the battery cell exceeds a predetermined threshold value.

### BRIEF DESCRIPTION OF THE FIGURES

The above and other objects, features and advantages of the present disclosure will be more apparent from the following detailed description taken in conjunction with the accompanying drawings:

FIG. 1 is a block diagram showing a battery diagnosing apparatus, according to an embodiment of the present disclosure;

FIG. 2A is a drawing showing an interface between an electrode and an electrolyte if the reaction with lithium occurs homogeneously at the electrode of a battery cell;

FIG. 2B is a drawing showing an interface between an electrode and an electrolyte if the reaction with lithium occurs heterogeneously at the electrode of a battery cell;

FIG. 3 is a graph showing a relationship between areal capacity and data on changes in pressure of a battery cell calculated by a battery diagnosing apparatus according to an embodiment of the present disclosure;

FIG. 4A is a graph showing a relationship between areal capacity and a change in pressure of a battery cell with an intercalation mechanism;

FIG. 4B is a graph showing a relationship between areal capacity and a change in pressure of a battery cell with a conversion mechanism;

FIG. 5A is a graph showing a relationship between areal capacity and a change in pressure of a battery cell with an N/P ratio exceeding 1;

FIG. 5B is a graph showing a relationship between areal capacity and a change in pressure of a battery cell with an N/P ratio being less than 1;

FIG. 6 is a graph showing a change in voltage and a change in pressure of a battery cell calculated by a battery diagnosing apparatus, according to an embodiment of the present disclosure;

FIG. 7A is a drawing showing an example of observing a change aspect of an electrode by using an optical microscope if charging of a battery cell begins;

FIG. 7B is a drawing showing an example of observing an aspect, in which the volume of an electrode expands during charging of a battery cell, by using an optical microscope;

FIG. 7C is a drawing showing an example of observing a phenomenon where lithium is plated inside an electrode during charging of a battery cell, by using an optical microscope;

FIG. 7D is a drawing showing an example of observing a phenomenon where lithium is plated on the top of an electrode during charging of a battery cell, by using an optical microscope;

FIG. 7E is a drawing showing an example of observing a phenomenon a dendrite of lithium is formed at the top of an electrode during charging of a battery cell, by using an optical microscope;

FIG. 8 is a flowchart for describing a battery diagnosing apparatus or a battery diagnosing method, according to an embodiment of the present disclosure;

FIG. 9 is a flowchart for describing a process of determining inhomogeneity of an electrodeposition reaction by a battery diagnosing apparatus or a battery diagnosing method, according to an embodiment of the present disclosure; and

FIG. 10 is a diagram showing a computing system associated with a battery diagnosing apparatus or a battery diagnosing method, according to an embodiment of the present disclosure.

### DETAILED DESCRIPTION

Hereinafter, some embodiments of the present disclosure will be described in detail with reference to the accompanying drawings. In adding reference numerals to components of each drawing, it should be noted that the same components include the same reference numerals, although they are indicated on another drawing. Furthermore, in describing the embodiments of the present disclosure, detailed descriptions of well-known functions or configurations will be omitted if they may make the subject matter of the present disclosure unnecessarily obscure.

In describing elements of an embodiment of the present disclosure, the terms first, second, A, B, (a), (b), and the like may be used herein. These terms are only used to distinguish one element from another element, but do not limit the corresponding elements irrespective of the nature, order, or priority of the corresponding elements. Moreover, the expression “at least one of A, B, or C or any combination thereof” may include “A, B, or C, or any combination thereof, such as AB, BC, AC, or ABC”.

Furthermore, unless otherwise defined, all terms used herein, including technical or scientific terms, include the same meaning as commonly understood by one of ordinary skill in the technical field to which the present disclosure belongs. It will be understood that terms used herein should be interpreted as including a meaning that is consistent with their meaning in the context of the present disclosure and the relevant art and will not be interpreted in an idealized or overly formal sense unless expressly so defined herein.

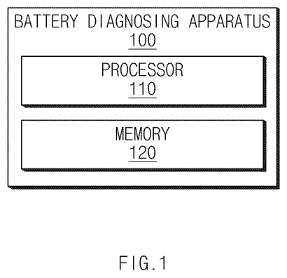

Hereinafter, embodiments of the present disclosure will be described in detail with reference to FIGS. 1 to 10.

FIG. 1 is a block diagram showing a battery diagnosing apparatus, according to an embodiment of the present disclosure.

Referring to FIG. 1, a battery diagnosing apparatus 100 according to an embodiment of the present disclosure may diagnose a battery of a vehicle. In this case, the battery diagnosing apparatus 100 may be integrated with internal control units of a vehicle and may be implemented with a separate device so as to be coupled with control units of the vehicle by a separate connection device.

According to an embodiment, the battery diagnosing apparatus 100 may include a processor 110, and a memory 120. The configuration of the battery diagnosing apparatus 100 shown in FIG. 1 is an example, and embodiments of the present disclosure are not limited thereto. For example, the battery diagnosing apparatus 100 may further include components not illustrated in FIG. 1.

According to an embodiment, the memory 120 may store instructions or data. For example, the memory 120 may store one instruction or two or more instructions that cause the battery diagnosing apparatus 100 to perform various operations if executed by the processor 110.

According to an embodiment, the memory 120 may be implemented as a single chipset with the processor 110 and may store various pieces of information associated with the battery diagnosing apparatus 100. For example, the memory 120 may store information about the operating history of the processor 110.

According to an embodiment, the memory 120 may include a non-volatile memory (such as read-only memory (ROM)) and a volatile memory (such as random access memory (RAM)). For example, data associated with the rate of change of pressure in a battery cell may be stored in the memory 120.

According to an embodiment, the processor 110 may calculate an integral value based on first data, and second data within a predetermined range.

According to an embodiment, the first data may include at least one of the rate of change of pressure of a battery cell, the acceleration of the rate of change of the pressure, or any combination thereof.

According to an embodiment, the battery to be diagnosed may be an all-solid-state battery. Furthermore, the battery may be a battery in a pack or may include at least one cell, such as a single cell. Here, the cell may include a full-cell configuration comprising an anode, a cathode, and an electrolyte.

Besides, in the present disclosure, the battery may include a battery used as a power source (electric power source) in a vehicle.

The pressure in a battery cell may include pressure that increases or decreases due to isotropic pressure distribution and pores within an electrode. Alternatively, the pressure of a battery cell may include pressure that increases or decreases due to deterioration of the battery cell.

According to an embodiment, the processor 110 may identify a pressure value of a battery cell measured by a pressure sensor that measures the pressure of the battery cell. The processor 110 may calculate the rate of change of pressure by differentiating the pressure value. The processor 110 may calculate the acceleration of the rate of change of pressure by differentiating the rate of change of pressure.

According to an embodiment, the rate of change of the pressure of the battery cell may include a value obtained by differentiating the value of pressure ‘P’ of the battery cell once with respect to the capacity ‘Q’ or time ‘t’ of the battery cell.

For example, the rate of change of pressure of a battery cell may include at least one of the pressure change amount dP/dQ of a battery cell per areal capacity, or the pressure change amount dP/dt of a battery cell per unit time, or any combination thereof.

According to an embodiment, the acceleration of the rate of change of pressure may include a value obtained by differentiating the value of pressure ‘P’ of a battery cell twice with respect to capacity ‘Q’or time ‘t’.

For example, the acceleration of the rate of change of pressure may include at least one of the change amount d²P/dQ² of the rate of change of pressure of a battery cell per areal capacity, or the change amount d²P/dt² of the rate of change of pressure of a battery cell per unit time, or any combination thereof.

Here, the areal capacity may include the capacity per unit area of an electrode plate of a battery cell.

According to an embodiment, the second data may include at least one of the areal capacity, including capacity per unit area of an electrode plate of the battery cell, or the time during which the battery cell is charged, or any combination thereof.

For example, the areal capacity may include the capacity per unit area of a negative plate of a battery cell.

According to an embodiment, the processor 110 may calculate the integral value by using a change amount d²P/dQ² of the rate of change of the pressure of a battery cell per areal capacity, and the areal capacity.

For example, the processor 110 may calculate the integral value by using a graph in which the change amount d²P/dQ² of the rate of change of pressure of the battery cell per areal capacity is set as a y-axis and the areal capacity is set as an x-axis. As a specific example, the processor 110 may derive the integral value by calculating the area of the graph. The processor 110 may calculate the integral value of the corresponding graph to evaluate the inhomogeneity across a cathode quantitatively.

According to an embodiment, in a constant current mode, constant charges move during a constant time, and thus the time or capacity may be replaced with a distance of a region in which the reaction proceeds.

According to an embodiment, the first-order derivative value dP/dx of pressure may indicate the slope (how fast the electrodeposition or reaction of lithium occurs) in the height direction of the electrode. The second-order derivative value d²P/dx² of pressure may indicate a change (whether the electrodeposition or the reaction of lithium occurs homogeneously) in slope in the height direction of the electrode.

For example, if the electrodeposition or reaction of lithium occurs uniformly over the entire electrode area, the first-order derivative value dP/dx of pressure may be constant, and the second-order derivative value d²P/dx² of pressure may be calculated to be small.

On the other hand, if the electrodeposition or reaction of lithium occurs intensively at a specific location of the electrode, the first-order derivative value dP/dx of pressure may change rapidly, and thus the second-order derivative value d²P/dx² of pressure may also be calculated to be large.

In other words, the second-order derivative value d²P/dx² of pressure may serve as an indicator for evaluating the homogeneity of the lithium reaction over the entire surface of the electrode, allowing users to analyze the battery using this indicator non-destructively.

Furthermore, a criterion for determining a time point at which lithium plating occurs during battery charging may be set based on the second-order derivative value d²P/dx² of pressure.

According to an embodiment, the processor 110 may calculate a FWHM value associated with a width of the second data relative to half a peak value of the first data. Here, the FWHM value may be a term indicating the width of a function, and may include a difference value between two independent variable values that is half of the maximum value of the function.

For example, in a graph of the acceleration of the rate of change of pressure of a battery cell according to areal capacity, the processor 110 may identify the maximum value of the acceleration of the rate of change of pressure of a battery cell, may identify areal capacities corresponding to a values that is half of the maximum value, and may calculate a difference between the identified areal capacities as a FWHM value.

According to an embodiment, the processor 110 may determine a condition of a battery cell based on the integral value and the FWHM value.

According to an embodiment, the processor 110 may determine the condition of the battery cell based on at least one of the homogeneity of the reaction occurring at an electrode of the battery cell, whether the electrodeposition reaction occurs, or whether a dendrite phenomenon occurs, or any combination thereof.

As a specific example, the processor 110 may determine at least one of whether lithium reaction occurs heterogeneously at a cathode, whether lithium is plated on the surface of the cathode, whether dendritic lithium grows on the surface of the cathode, or whether the dendrite phenomenon occurs at the cathode, or any combination thereof based on the integral value and FWHM value.

According to an embodiment, the processor 110 may determine the condition of the battery cell based on a characteristic value obtained by dividing the integral value by the FWHM value. That is, the processor 110 may determine the condition of the battery cell based on the value obtained by dividing the integral value by the FWHM value.

For example, the processor 110 may divide the integral area of the graph for the second-order derivative value of pressure by the FWHM and may normalize the divided result so as to be converted into a characteristic value. In this way, even though a test condition is changed due to various variables such as the type of cathode, current density, and temperature, the condition of the battery cell may be evaluated by applying consistent criteria.

In other words, the inhomogeneity of the reaction occurring during a battery charging process may be quantitatively analyzed by dividing the integral area of the graph for the second-order derivative value of pressure by the FWHM so as to be normalized.

According to an embodiment, the processor 110 may determine the condition of the battery cell based on the result of comparing the characteristic value with a reference value associated with the dendrite phenomenon.

According to an embodiment, the processor 110 may compare the characteristic value, which is obtained by dividing the integral value by the FWHM value, with the reference value associated with the dendrite phenomenon. The dendrite phenomenon may refer to the phenomenon that metal ions grow while being unevenly plated on the surface of the cathode during battery charging. The dendrite phenomenon may cause safety issues and performance degradation of a battery. The dendrite phenomenon may include the phenomenon that metal ions are plated not only from the surface of the cathode but also from the inside of the cathode. If the dendrite phenomenon occurs, the battery may not function properly.

For example, as the inhomogeneity of the reaction occurring on the surface of the electrode is higher, the possibility that the dendrite phenomenon occurs is higher. On the other hand, as the inhomogeneity of the reaction occurring on the surface of the electrode is lower, the possibility that the dendrite phenomenon occurs is lower.

According to an embodiment, the reference value may include a value at which the dendrite phenomenon begins to occur. For example, if the characteristic value exceeds the reference value, the dendrite phenomenon may occur.

According to an embodiment, the reference value may be determined based on the electrochemical operating principle at the electrode of a battery cell. The electrochemical operating principle at the electrodes of a battery cell may include a charging mechanism.

For example, a battery with an intercalation mechanism and a battery with a conversion mechanism may have different reference values from each other. Here, a material with an intercalation mechanism may include graphite, and a material with a conversion mechanism may include lithium.

As a specific example, an electrode of the material with an intercalation mechanism may experience a dendrite phenomenon if the characteristic value exceeds 1. In this case, the reference value for the electrode of the material with an intercalation mechanism may be determined as 1.

The electrode of the material with a conversion mechanism may experience the dendrite phenomenon if the characteristic value exceeds 6. In this case, the reference value for the electrode of the material with a conversion mechanism may be determined as 6.

According to an embodiment, the processor 110 may determine the condition of the battery cell as a state where the dendrite phenomenon occurs at an electrode of the battery cell, based on the result indicating that the characteristic value exceeds the reference value.

According to an embodiment, if the characteristic value exceeds the reference value, the processor 110 may determine that the inhomogeneity of the reaction is high. If the characteristic value does not exceed the reference value, the processor 110 may determine that the inhomogeneity of the reaction is low.

According to an embodiment, the processor 110 may determine the condition of the battery cell based on the capacity of the cathode of the battery cell being lower than the capacity of the anode of the battery cell.

For example, if an N/P ratio is greater than 1, the metal ions may be sufficiently accommodated in the cathode, thereby reducing the possibility of the dendrite phenomenon occurring. Here, the N/P ratio may mean the ratio of the capacity of the battery cell's cathode to the capacity of the battery cell's anode. Accordingly, the processor 110 may determine the condition of the battery cell based on whether the N/P ratio is less than 1.

According to an embodiment, after the charge cycle of the battery cell exceeds the predetermined number of times, the processor 110 may determine the condition of the battery cell based on the integral value and the FWHM value. Here, the predetermined number of times may be set to the number of times that data associated with the pressure of the battery cell is consistently identified. As a specific example, if the pressure of the battery cell starts to be measured consistently from the third round after the first battery cell is produced, the predetermined number of times may be set to three times.

According to an embodiment, the processor 110 may calculate an integral value in consideration of a region where the slope of pressure continuously increases starting from an inflection point of the pressure during a process of charging a battery cell.

For example, the processor 110 may calculate an integral value from a first time point to a second time point. Here, the first time point may include a time point at which charging of the battery cell begins, or a time point at which the areal capacity is 0. The second time point may include a time point at which the acceleration of the rate of change of pressure of the battery cell becomes 0.

As a specific example, in a graph where the change amount d²P/dQ² of the rate of change of pressure of the battery cell per areal capacity is set as the y-axis and the areal capacity is set as the x-axis, the integral value may be calculated by using a graph area from a point where the areal capacity is 0, to a point where the change amount of the rate of change of pressure becomes 0.

According to an embodiment, the processor 110 may stop charging the battery cell based on determining that the degree to which the dendrite phenomenon occurs at an electrode of the battery cell exceeds a predetermined threshold value.

According to an embodiment, the processor 110 may quantitatively determine the degree to which dendrites are formed during the process of charging a battery, in consideration of the influence of the dendrite phenomenon on the battery. Additionally, if it is determined that the degree to which dendrite is formed exceeds the threshold value, a control signal may be output to adjust the charging current or to stop charging.

For example, as dendrite growth progresses, the risk of short circuits between electrodes increases, which can lead to thermal runaway and performance degradation of the battery. To prevent this, the processor 110 may analyze a variation pattern of the second-order derivative value d²P/dx² of pressure. If dendrite formation is detected, the processor 110 may suppress dendrite growth by reducing the charging current or adjusting a charging profile.

Moreover, the processor 110 may predict the possibility that the dendrite phenomenon occurs, and may optimize the charging strategy in consideration of the battery's charging history and environmental conditions (e.g., temperature, charging speed, and the like).

Furthermore, the processor 110 may detect the possibility of an internal short circuit due to dendrite formation in advance in conjunction with a battery management system (BMS), may provide a warning signal to a user, or completely stop charging if necessary to ensure battery safety.

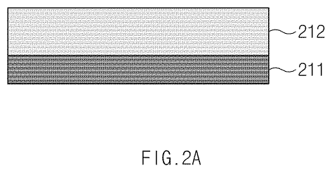

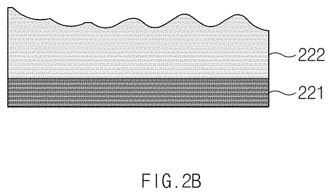

FIG. 2A is a drawing showing an interface between an electrode and an electrolyte if the reaction with lithium occurs homogeneously at the electrode of a battery cell.

Lithium-ion batteries receive energy from an external power source during charging, and thus, lithium ions may move from an anode to a cathode. For example, at the anode, lithium ions may be released and electrons may be generated. At the cathode, lithium ions moving via the electrolyte may be intercalated between layers in a graphite-based cathode material (an intercalation reaction). Accordingly, energy may be accumulated as lithium ions are stored inside the cathode.

Lithium-ion batteries may generate current if the stored lithium ions move from the cathode to the anode during discharge. For example, at the cathode, lithium ions may escape from a graphite layer and may move via the electrolyte to the anode. At the anode, the released lithium ions may move into the anode material and be re-intercalated.

FIG. 2A, according to an embodiment, may illustrate a cathode 211 of a lithium ion battery and a reaction region 212 of lithium ions.

According to an embodiment, as the lithium ion reaction is homogeneous in the reaction region 212 of lithium ions, the acceleration (i.e., the second-order derivative value d²P/dx² of pressure) of the rate of change of pressure in the battery cell may appear small.

For example, if electrodeposition or reaction of lithium occurs homogeneously over the entire electrode area, the reaction rate is constant, and thus the first-order derivative value dP/dx of pressure may be maintained to be constant. Accordingly, the second-order derivative value d²P/dx² of pressure may appear small.

FIG. 2B is a drawing showing an interface between an electrode and an electrolyte if the reaction with lithium occurs heterogeneously at the electrode of a battery cell.

FIG. 2B, according to an embodiment, may illustrate a cathode 221 of a lithium ion battery and a reaction region 222 of lithium ions.

According to an embodiment, as the lithium ion reaction is heterogeneous in the reaction region 222 of lithium ions, the acceleration (i.e., the second-order derivative value d²P/dx² of pressure) of the rate of change of pressure in the battery cell may appear large.

For example, if electrodeposition or reaction of lithium occurs intensively at a specific location on an electrode, the first-order derivative value dP/dx of pressure may change rapidly as the reaction rate changes. Accordingly, the second-order derivative value d²P/dx² of pressure may appear large.

According to an embodiment, referring to FIGS. 2A and 2B, the reaction homogeneity inside the lithium-ion battery may be evaluated by analyzing the second-order derivative value d²P/dx² of pressure. In this way, the performance and safety of the battery may be predicted.

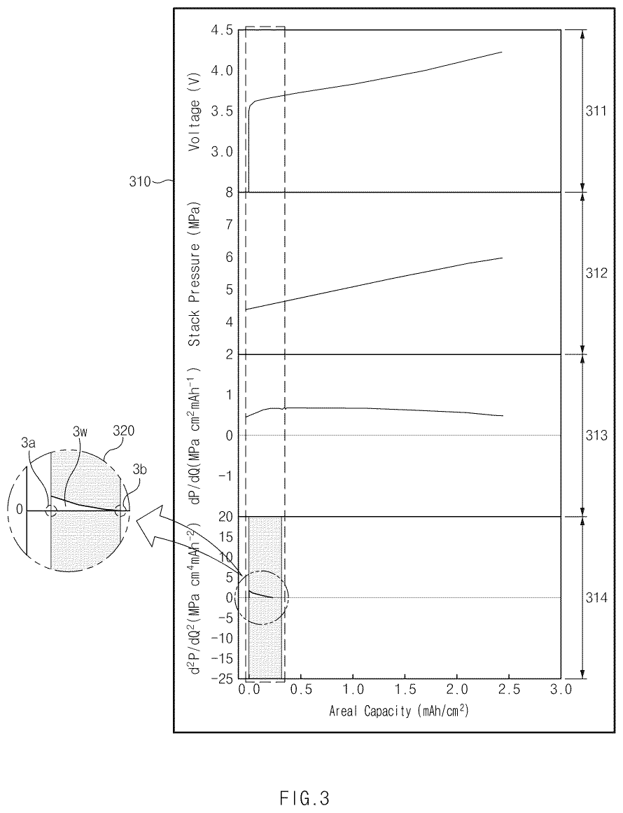

FIG. 3 is a graph showing a relationship between areal capacity and data on changes in pressure of a battery cell calculated by a battery diagnosing apparatus according to an embodiment of the present disclosure.

According to an embodiment, FIG. 3 is a graph showing changes in voltage, stack pressure, the first-order derivative value dP/dQ of pressure, and the second-order derivative value d²P/dQ² of pressure according to areal capacity.

For example, FIG. 3 may include a graph 311 for the voltage according to the areal capacity, a graph 312 for the stack pressure according to the areal capacity, a graph (313) for the first-order derivative value dP/dQ of pressure according to the areal capacity, and a graph (314) for the second-order derivative value d²P/dQ² of pressure according to the areal capacity.

According to an embodiment, referring to the graph 311 for the voltage, the voltage of a battery may increase as the battery is charged.

According to an embodiment, referring to the graph 312 for the stack pressure, the stack pressure of the battery may increase as the battery is charged. Here, the stack pressure may mean the pressure that is applied by individual cells to each other within a battery cell or in a battery pack.

According to an embodiment, referring to the graph 313 for the first-order derivative value dP/dQ of pressure, if the areal capacity is small, the first-order derivative value of the pressure may change to increase.

According to an embodiment, referring to the graph 314 for the second-order derivative value d²P/dQ² of pressure, in a section where the first-order derivative value of pressure changes, the second-order derivative value d²P/dQ² of pressure may also change. Accordingly, the area of an integral area 3w of the graph 314 for the second-order derivative value d²P/dQ² of pressure may be calculated.

For example, referring to an enlarged view 320 of a section where the first-order derivative value of pressure changes, the area of an integral area 3w from a point 3a, where the areal capacity is 0, to a point 3 b where the second-order derivative value d²P/dQ² of pressure is 0 may be calculated.

The battery diagnosing apparatus according to an embodiment may quantitatively analyze the inhomogeneity of a reaction occurring during a battery charging process by dividing the area of the integral area 3w of the graph 314 for the second-order derivative value d²P/dQ² of pressure by the FWHM so as to be normalized.

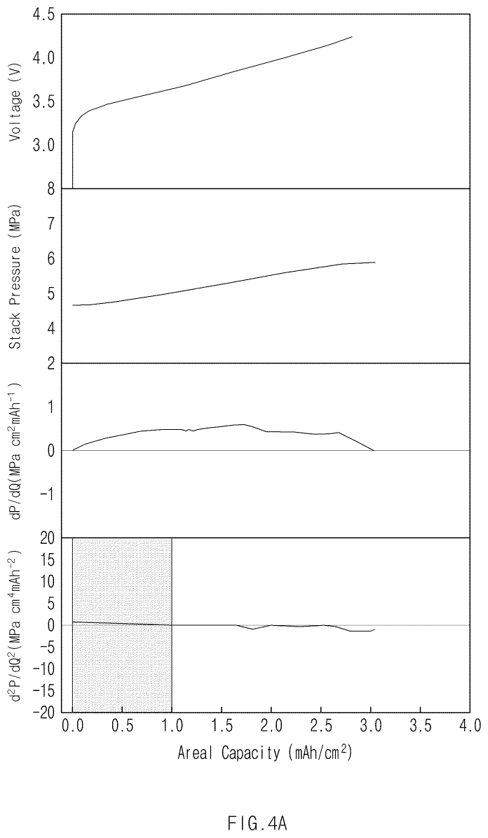

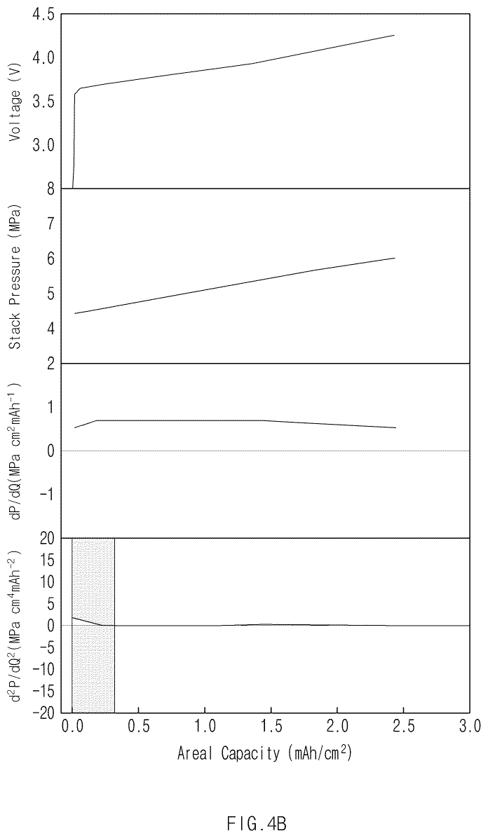

FIG. 4A is a graph showing a relationship between areal capacity and a change in pressure of a battery cell with an intercalation mechanism.

FIG. 4B is a graph showing a relationship between areal capacity and a change in pressure of a battery cell with a conversion mechanism.

According to an embodiment, similarly to FIG. 3, each of FIGS. 4A and 4B may include a graph showing changes in voltage, stack pressure, first-order derivative value dP/dQ of pressure, and second-order derivative value d²P/dQ² of pressure according to areal capacity.

According to an embodiment, a material with an intercalation mechanism may typically include graphite, and a material with a conversion mechanism may typically include lithium.

Referring to FIG. 4A, according to an embodiment, the homogeneity of the reaction may be high in the electrode of a battery cell with the intercalation mechanism.

On the other hand, referring to FIG. 4B, according to an embodiment, the inhomogeneity of the reaction may be high in the electrode of the battery cell with the conversion mechanism. For example, a lithium plating reaction may occur at the electrode of the battery cell with the conversion mechanism.

According to an embodiment, as the inhomogeneity of the lithium electrodeposition is high, the characteristic value obtained by dividing the area of the integral area by the FWHM may be calculated to be great. On the other hand, the characteristic value of an electrode including silver Ag, including the affinity for lithium, may be calculated to be small.

According to an embodiment, the characteristic value of 1 or more may be calculated in the electrode of the battery cell with the conversion mechanism. On the other hand, the characteristic value of less than 1 may be calculated in the electrode of the battery cell with the intercalation mechanism.

Referring to FIGS. 4A and 4B, according to an embodiment, a battery cell with an intercalation mechanism may cause a reaction with low inhomogeneity throughout the electrode during charging, and a battery cell with a conversion mechanism may cause a reaction with high inhomogeneity during the charging process.

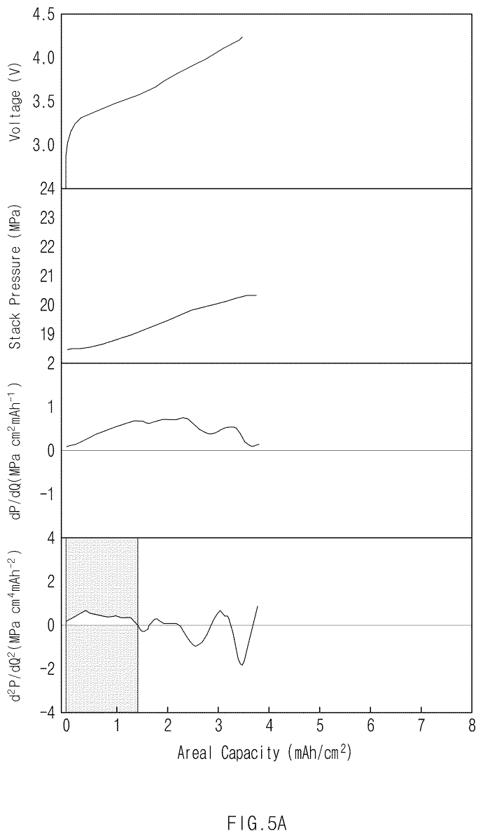

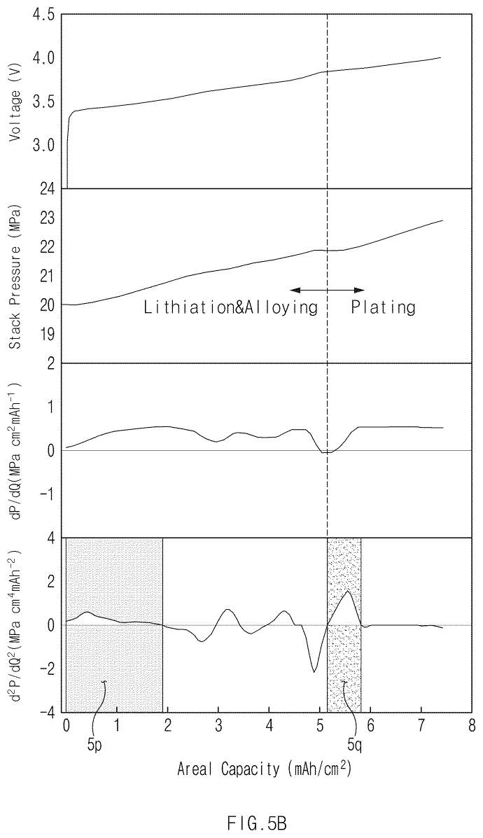

FIG. 5A is a graph showing a relationship between areal capacity and a change in pressure of a battery cell with an N/P ratio exceeding 1.

According to an embodiment, an N/P ratio exceeding 1 may indicate that the cathode has a higher capacity than the anode. If the N/P ratio exceeds 1, the capacity of the cathode is high, and thus the cathode may sufficiently accommodate lithium during charging, and the possibility that lithium is evenly intercalated may increase. That is, since lithium ions are not supersaturated, the possibility of lithium metal plating is reduced, thereby suppressing dendrite formation.

Accordingly, there is sufficient diffusion space for lithium ions within the cathode, thereby reducing the phenomenon that lithium is intensively intercalated in a specific local region, and increasing the homogeneity of the reaction. For this reason, a rate of change of pressure (the first-order derivative value of pressure) and an acceleration value (the second-order derivative value of pressure) of the rate of change of pressure may appear relatively small.

FIG. 5B is a graph showing a relationship between areal capacity and a change in pressure of a battery cell with an N/P ratio being less than 1.

According to an embodiment, an N/P ratio less than 1 may indicate that the capacity of a cathode is lower than that of an anode. If the N/P ratio is less than 1, the capacity of the cathode is limited, and thus it may not sufficiently accommodate lithium ions during the charging process. In other words, the possibility that excess lithium is plated on an electrode surface in the form of metallic lithium increases, thereby promoting dendrite growth.

Accordingly, because the lithium storage space of the cathode is insufficient, there is a high possibility that lithium is excessively intercalated only in specific regions, and the inhomogeneity of the reaction may increase as a local lithium concentration difference increases. For this reason, a rate of change of pressure (the first-order derivative value of pressure) and an acceleration value (the second-order derivative value of pressure) of the rate of change of pressure may significantly increase.

Accordingly, if the N/P ratio is less than 1, it may be useful to determine inhomogeneity by using a characteristic value obtained by dividing the integral area of a graph for the acceleration of the rate of change of pressure by the FWHM.

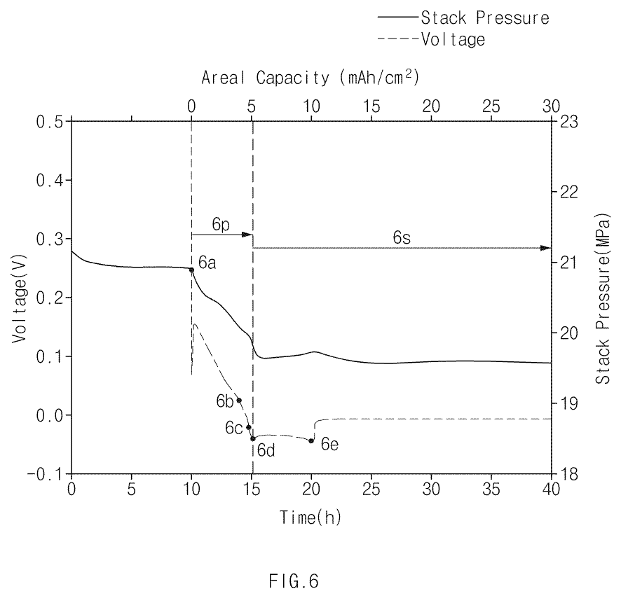

FIG. 6 is a graph showing a change in voltage and a change in pressure of a battery cell calculated by a battery diagnosing apparatus, according to an embodiment of the present disclosure.

The x-axis of a graph of FIG. 6 according to an embodiment may represent time (displayed at the bottom of the graph) or areal capacity (displayed at the top of the graph). The y-axis of the graph in FIG. 6 may represent a voltage (displayed on the left side of the graph) or stack pressure (displayed on the right side of the graph).

Referring to FIG. 6, according to an embodiment, an intercalation or alloying reaction may occur from point 6a where the areal capacity is 0.

According to an embodiment, a lithium plating phenomenon may occur from point 6d where the areal capacity exceeds 5. The lithium plating phenomenon may include a dendrite phenomenon.

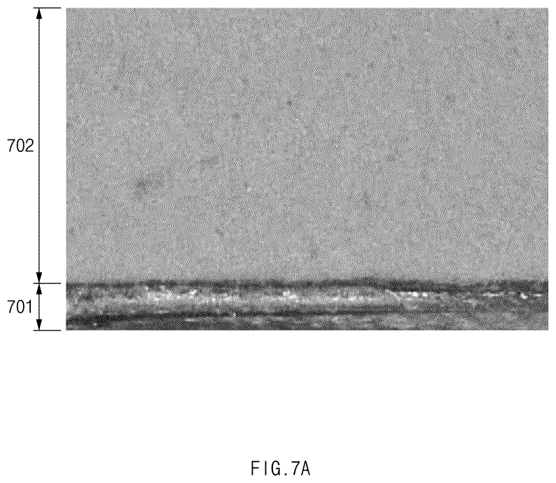

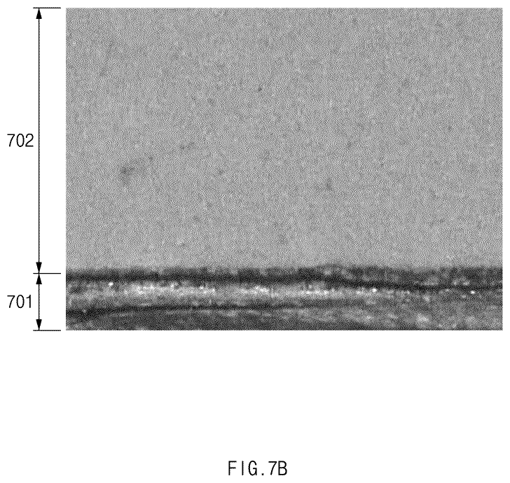

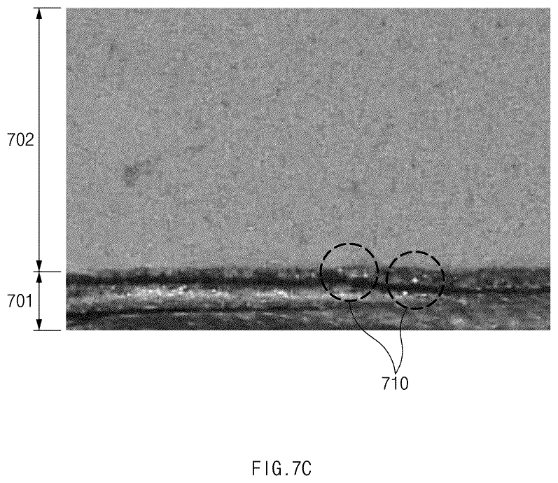

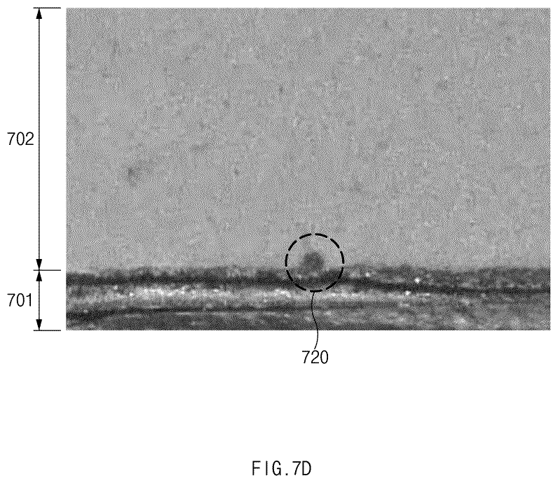

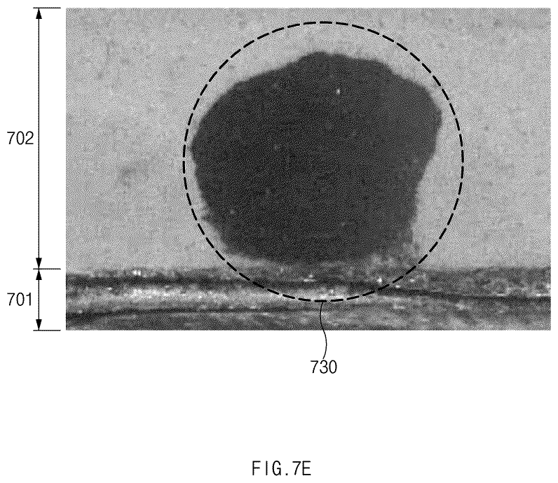

FIGS. 7A, 7B, 7C, 7D, and 7E are drawings showing examples, in which a change aspect of an electrode is observed by using an optical microscope during charging of a battery cell.

According to an embodiment, FIGS. 7A, 7B, 7C, 7D, and 7E may show results of observing changes in electrodes while a battery cell is being charged by using an optical microscope, assuming that an N/P ratio is less than 1.

FIGS. 7A, 7B, 7C, 7D, and 7E may illustrate an electrode 701 and an electrolyte 702 of the battery cell.

According to an embodiment, FIGS. 7A, 7B, 7C, 7D, and 7E may represent the results of observing the change patterns of the electrode at points 6a, 6b, 6c, 6d, and 6e of FIG. 6, respectively.

For example, FIG. 7A may represent the observation result at point 6a of FIG. 6; FIG. 7B may represent the observation result at point 6b of FIG. 6; FIG. 7C may represent the observation result at point 6c of FIG. 6; and, FIG. 7D may represent the observation result at point 6d of FIG. 6.

FIG. 7A is a drawing showing an example of observing a change in the aspect of an electrode by using an optical microscope when charging a battery cell begins.

FIG. 7B is a drawing showing an example of observing an aspect, in which the volume of an electrode expands during charging of a battery cell, by using an optical microscope.

Referring to FIGS. 7A and 7B, according to an embodiment, it may be seen that the volume of the electrode 701 expands as the battery cell is charged.

FIG. 7C is a drawing showing an example of observing a phenomenon where lithium is plated inside an electrode during charging of a battery cell, by using an optical microscope.

Referring to FIG. 7C, according to an embodiment, it may be seen that the intercalation of lithium ions that the electrode 701 may accommodate is terminated, and a phenomenon 710 that lithium is plated inside the electrode 701 occurs.

FIG. 7D is a drawing showing an example of observing a phenomenon where lithium is plated on the top of an electrode during charging of a battery cell, by using an optical microscope.

Referring to FIG. 7D, according to an embodiment, it may be seen that a phenomenon 720 occurs in which the dendrite of lithium is formed from the top of the electrode 701 as lithium plating continues.

FIG. 7E is a drawing showing an example of observing a phenomenon where a dendrite of lithium is formed at the top of an electrode during charging of a battery cell, by using an optical microscope.

Referring to FIG. 7E, according to an embodiment, it may be seen that a phenomenon 730, in which the dendrite of lithium grows and becomes larger in an electrolyte 702, occurs.

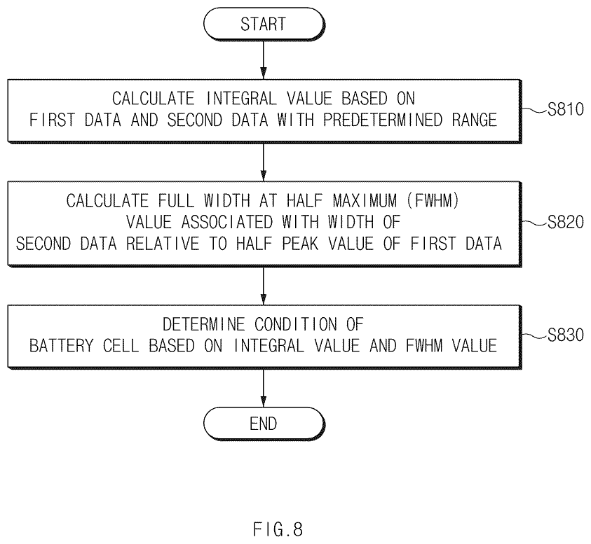

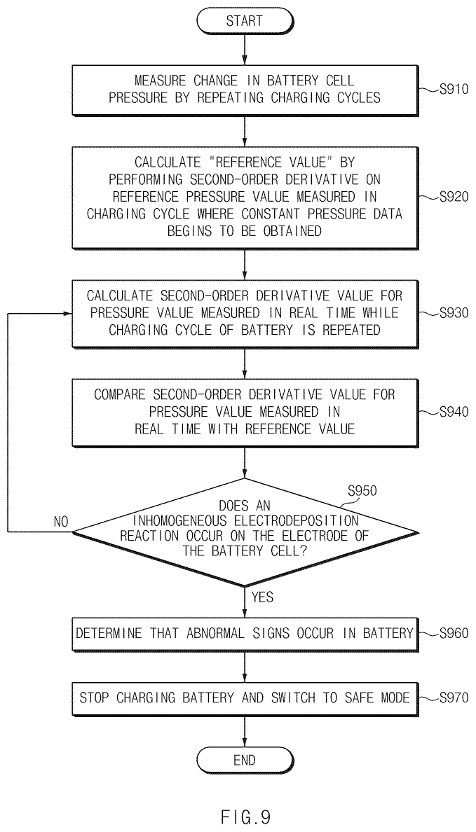

Hereinafter, a battery diagnosing apparatus or a battery diagnosing method according to an embodiment of the present disclosure will be specifically described with reference to FIGS. 8 and 9.

Hereinafter, the battery diagnosing apparatus 100 of FIG. 1 may perform the process of FIG. 8 or 9. In addition, in a description of FIG. 8 or 9, it may be understood that an operation described as being performed by a battery diagnosing apparatus is controlled by the processor 110 of the battery diagnosing apparatus 100.

FIG. 8 is a flowchart for describing a battery diagnosing apparatus or a battery diagnosing method, according to an embodiment of the present disclosure.

According to an embodiment, the battery diagnosing apparatus may calculate an integral value based on first data, and second data with a predetermined range (S810). The first data may include at least one of: a rate of change of pressure of a battery cell; an acceleration of the rate of change of the pressure; or any combination thereof. The second data may include at least one of: an areal capacity including capacity per unit area of an electrode plate of the battery cell; a charging time of the battery cell; or any combination thereof.

According to an embodiment, the battery diagnosing apparatus may calculate a FWHM value associated with a width of the second data relative to half a peak value of the first data (S820).

According to an embodiment, the battery diagnosing apparatus may determine a condition of the battery cell based on the integral value and the FWHM value (S830).

FIG. 9 is a flowchart for describing a process of determining inhomogeneity of an electrodeposition reaction by a battery diagnosing apparatus or a battery diagnosing method, according to an embodiment of the present disclosure.

According to an embodiment, the battery diagnosing apparatus may measure the change in pressure of a battery cell by repeatedly performing charging cycle of a battery (S910). If lithium ions are intercalated or plated into an electrode inside the battery cell, the pressure may change. In a process of repeatedly charging and discharging the battery cell, the battery diagnosing apparatus may measure the change in pressure in real time.

According to an embodiment, the battery diagnosing apparatus may calculate a reference value by performing a second-order derivative on a reference pressure value measured in a charging cycle where constant pressure data begins to be obtained (S920). The second-order derivative value may indicate the acceleration of the rate of change of pressure, which may be used to evaluate the reaction homogeneity on an electrode surface.

According to an embodiment, the battery diagnosing apparatus may calculate a second-order derivative value for a pressure value measured in real time while the charging cycle of the battery is repeated (S930).

According to an embodiment, the battery diagnosing apparatus may compare the second-order derivative value for the pressure value measured in real time with the reference value (S940). If the difference between the second-order derivative value for the pressure value measured in real time and the reference value is small, it may be determined that the internal reaction of the battery is stable and maintains a uniform state. On the other hand, if the second-order derivative value for the pressure value measured in real time is greater than the reference value, there is a high possibility that local lithium plating or inhomogeneous electrodeposition reaction may occur.

According to an embodiment, the battery diagnosing apparatus may determine whether the inhomogeneous electrodeposition reaction occurs on an electrode of a battery cell (S950). For example, if the second-order derivative value for the pressure value measured in real time exceeds the reference value, it may be determined that the inhomogeneous lithium electrodeposition reaction occurs on the electrode surface.

According to an embodiment, if it is determined that an inhomogeneous electrodeposition reaction occurs, the battery diagnosing apparatus may determine that abnormal signs are present in the battery (S960). If dendrites grow inside the battery, the risk of short circuits between electrodes increases and the possibility of thermal runaway increases. Accordingly, it may be determined that abnormal signs occur in the battery.

On the other hand, if determining that the inhomogeneous electrodeposition reaction does not occur, the battery diagnosing apparatus may continuously calculate the second-order derivative value for the pressure value measured in real time (S930).

According to an embodiment, if determining that abnormal signs occur in the battery, the battery diagnosing apparatus may stop charging the battery and may switch to a safe mode (S970). In the safe mode, the charging of a battery may be restricted or a battery management system (BMS) may intervene, thereby activating a protection function of adjusting the current and voltage. In this way, the risk of internal short circuits and overheating of the battery may be prevented, thereby maintaining the safety of the battery.

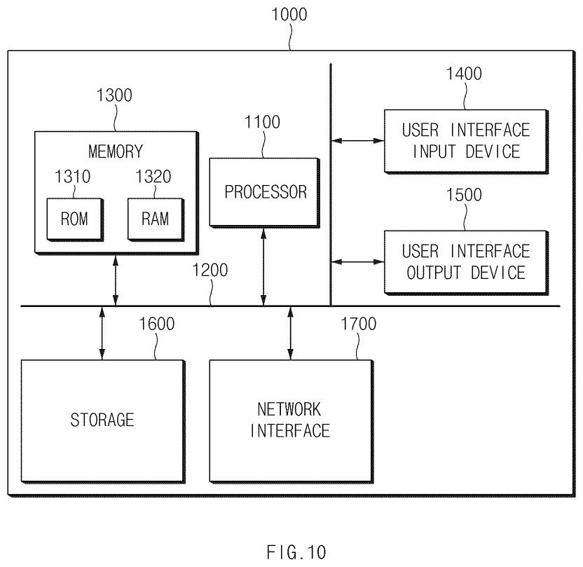

FIG. 10 is a diagram illustrating a computing system associated with a battery diagnosing apparatus or a battery diagnosing method, according to an embodiment of the present disclosure.

Referring to FIG. 10, a computing system 1000 may include at least one processor 1100, a memory 1300, a user interface input device 1400, a user interface output device 1500, a storage 1600, and a network interface 1700, which are connected with each other via a bus 1200.

The processor 1100 may be a central processing unit (CPU) or a semiconductor device that processes instructions stored in the memory 1300 and/or the storage 1600. Each of the memory 1300 and the storage 1600 may include various types of volatile or nonvolatile storage media. For example, the memory 1300 may include a read only memory (ROM) 1310 and a random access memory (RAM) 1320.

Accordingly, the operations of the method or algorithm described in connection with the embodiments disclosed in the specification may be directly implemented using a hardware module, a software module, or a combination of the hardware module and the software module, which is executed by the processor 1100. The software module may reside on a storage medium (i.e., the memory 1300 and/or the storage 1600) such as a random access memory (RAM), a flash memory, a read only memory (ROM), an erasable and programmable ROM (EPROM), an electrically EPROM (EEPROM), a register, a hard disk drive, a removable disc, or a compact disc-ROM (CD-ROM).

The storage medium may be coupled to the processor 1100. The processor 1100 may read out information from the storage medium and may write information into the storage medium. Alternatively, the storage medium may be integrated with the processor 1100. The processor and storage medium may be implemented with an application specific integrated circuit (ASIC). The ASIC may be provided in a user terminal. Alternatively, the processor and storage medium may be implemented with separate components in the user terminal.

The above description is merely an example of the technical idea of the present disclosure, and various modifications and variations may be made by one skilled in the art without departing from the essential characteristic of the present disclosure.

Accordingly, embodiments of the present disclosure are intended not to limit but to explain the technical idea of the present disclosure, and the scope and spirit of the present disclosure are not limited by the above embodiments. The scope of protection of the present disclosure should be construed by the attached claims, and all equivalents thereof should be construed as being included within the scope of the present disclosure.

The present technology may detect the plating of metal on an electrode during the operation of a battery.

Moreover, the present technology may quantitatively analyze the homogeneity of the electrode internal reaction and the presence of lithium electrodeposition based on pressure change data during the charging process of a battery.

Furthermore, the present technology may non-destructively evaluate the condition of a battery cell by quantifying the heterogeneity of the electrodeposition reaction using the first-order derivative value and the second-order derivative value of the pressure of the battery cell.

Also, the present technology may provide a criterion for comparing lithium electrodeposition and reaction heterogeneity under various conditions by normalizing the integral area of a graph for the second-order derivative value of the pressure of the battery cell to a FWHM value.

Besides, the present technology may provide a criterion for evaluating the stability of a battery by quantitatively analyzing the time at which lithium plating begins within a battery cell and the progress of the lithium plating.

In addition, the present technology may extend battery life and improve safety by detecting lithium dendrite growth issues occurring in battery cells early.

Additionally, a variety of effects directly or indirectly understood via the present disclosure may be provided.

Hereinabove, although the present disclosure was described with reference to exemplary embodiments and the accompanying drawings, the present disclosure is not limited thereto, but may be variously modified and altered by those skilled in the art to which the present disclosure pertains without departing from the spirit and scope of the present disclosure claimed in the following claims.

1. A battery diagnosing apparatus comprising:
a memory configured to store program instructions; and
a processor configured to execute the program instructions;
wherein the program instructions comprise:
calculating an integral value based on first data, and second data within a predetermined range;
calculating a Full Width at Half Maximum (FWHM) value associated with a width of the second data relative to half a peak value of the first data; and
determining a condition of a battery cell based on the integral value and the FWHM value;
wherein the first data includes at least one of: a rate of change of pressure of the battery cell; an acceleration of the rate of change of the pressure; or any combination thereof; and
wherein the second data includes at least one of: an areal capacity comprising a capacity per unit area of an electrode plate of the battery cell; a charging time of the battery cell; or any combination thereof; and
stopping charging the battery cell upon determining that the extent of dendrite formation at an electrode of the battery cell exceeds a predetermined threshold value.

2. The battery diagnosing apparatus of claim 1, wherein the instructions further comprise:
identifying a pressure value of the battery cell measured by a pressure sensor configured to measure the pressure of the battery cell;
calculating the rate of change of the pressure by differentiating the pressure value; and
calculating the acceleration of the rate of change of the pressure by differentiating the rate of change of the pressure.

3. The battery diagnosing apparatus of claim 1, wherein the instructions further comprise:
determining the condition of the battery cell based on a characteristic value obtained by dividing the integral value by the FWHM value.

4. The battery diagnosing apparatus of claim 3, wherein the instructions further comprise:
determining the condition of the battery cell based on a result of comparing the characteristic value with a reference value associated with a dendrite phenomenon.

5. The battery diagnosing apparatus of claim 4, wherein the instructions further comprise:
determining the condition of the battery cell as a state where the dendrite phenomenon occurs at an electrode of the battery cell, based on a result indicating that the characteristic value exceeds the reference value.

6. The battery diagnosing apparatus of claim 4, the reference value is determined based on an electrochemical operating principle at an electrode of the battery cell.

7. The battery diagnosing apparatus of claim 1, wherein the instructions further comprise:
determining the condition of the battery cell based on a capacity of a cathode of the battery cell being lower than a capacity of an anode of the battery cell.

8. The battery diagnosing apparatus of claim 1, wherein the instructions further comprise:
determining the condition of the battery cell based on the integral value and the FWHM value after a charge cycle of the battery cell exceeds a predetermined number of times.

9. The battery diagnosing apparatus of claim 1, wherein the instructions further comprise:
calculating the integral value from a first time point to a second time point,
wherein the first time point corresponds to either a time point at which charging of the battery cell begins, or a time point at which the areal capacity is 0, and
wherein the second time point corresponds to a time point at which the acceleration of the rate of change of pressure of the battery cell becomes 0.

10. The battery diagnosing apparatus of claim 1, wherein the instructions further comprise:
switching to a safe mode configured to restrict charging or activate a protection function for adjusting the current and voltage.

11. A battery diagnosing method, the method comprising:
calculating, by a processor, an integral value based on first data, and second data with a predetermined range;
calculating, by the processor, a FWHM value associated with a width of the second data relative to half a peak value of the first data; and
determining, by the processor, a condition of a battery cell based on the integral value and the FWHM value;
wherein the first data includes at least one of: a rate of change of pressure of the battery cell; an acceleration of the rate of change of the pressure; or any combination thereof; and
wherein the second data includes at least one of: an areal capacity comprising a capacity per unit area of an electrode plate of the battery cell; a charging time of the battery cell; or any combination thereof; and
stopping, by the processor, charging of the battery cell upon determining that the extent of dendrite formation at an electrode of the battery cell exceeds a predetermined threshold value.

12. The method of claim 11, wherein the calculating, by the processor, the integral value based on the first data, and the second data with the predetermined range comprises:
identifying, by the processor, a pressure value of the battery cell measured by a pressure sensor configured to measure the pressure of the battery cell;
calculating, by the processor, the rate of change of the pressure by differentiating the pressure value; and
calculating, by the processor, the acceleration of the rate of change of the pressure by differentiating the rate of change of the pressure.

13. The method of claim 11, wherein the determining, by the processor, the condition of the battery cell based on the integral value and the FWHM value comprises:
determining, by the processor, the condition of the battery cell based on a characteristic value obtained by dividing the integral value by the FWHM value.

14. The method of claim 13, wherein the determining, by the processor, the condition of the battery cell based on the integral value and the FWHM value comprises:
determining, by the processor, the condition of the battery cell based on a comparison of the characteristic value with a reference value associated with occurrence of a dendrite phenomenon.

15. The method of claim 14, wherein the determining, by the processor, the condition of the battery cell based on the integral value and the FWHM value comprises:
determining, by the processor, the condition of the battery cell as a state where the dendrite phenomenon occurs at an electrode of the battery cell, based on a result indicating that the characteristic value exceeds the reference value.

16. The method of claim 14, wherein the reference value is determined based on an electrochemical operating principle at an electrode of the battery cell.

17. The method of claim 11, wherein the determining, by the processor, the condition of the battery cell based on the integral value and the FWHM value comprises:
determining, by the processor, the condition of the battery cell based on a capacity of a cathode of the battery cell being lower than a capacity of an anode of the battery cell.

18. The method of claim 11, wherein the determining, by the processor, the condition of the battery cell based on the integral value and the FWHM value comprises:
determining, by the processor, the condition of the battery cell based on the integral value and the FWHM value after a charge cycle of the battery cell exceeds a predetermined number of times.

19. The method of claim 11, wherein the calculating, by the processor, the integral value based on the first data, and the second data with the predetermined range comprises:
calculating, by the processor, the integral value from a first time point to a second time point,
wherein the first time point corresponds to either a time point at which charging of the battery cell begins, or a time point at which the areal capacity is 0, and
wherein the second time point corresponds to a time point at which the acceleration of the rate of change of pressure of the battery cell becomes 0.

20. The method of claim 11, further comprising:
switching to a safe mode configured to restrict charging or activate a protection function for adjusting the current and voltage.
